(19) United States
(12) Patent Application Publication
(10) Pub. No.: US 2009/0222216 A1
(43) Pub. Date: Sep. 3, 2009

(54) System and Method to Improve Accuracy of a Polymer

(75) Inventors: Andrew D. Hibbs, La Jolla, CA (US); Geoffrey Alden Barrall, San Diego, CA (US); Daniel K. Lathrop, San Diego, CA (US)

Correspondence Address: DIEDERIKS & WHITELAW, PLC, 12471 DILLINGHAM SQUARE, #301, WOODBRIDGE, VA, 22192, US

(73) Assignee: Electronic Bio Sciences, LLC, San Diego, CA (US)

(21) Appl. No.: 12/395,682

(22) Filed: Mar. 1, 2009

Related U.S. Application Data
(60) Provisional application No. 61/032,318, filed on Feb. 28, 2008.

(51) Int. Cl. G06F 19/00; G01R 33/48

(52) U.S. Cl. 702/20

(57) ABSTRACT

The sequencing of individual monomers (e.g., a single nucleotide) of a polymer (e.g., DNA, RNA) is improved by reducing the motion of the polymer due to thermally-driven diffusion to reduce the spatial error in the position of the polymer within a measurement device. A major system parameter, such as average translocation velocity or measurement time, is selected based on the characteristics of the sensing system utilized, and an algorithm jointly optimizes the sequencing order error rate and the monomer identification error rate of the system.

### CROSS-REFERENCE TO RELATED APPLICATIONS

The present invention claims the benefit of U.S. Provisional Patent Application Ser. No. 61/032,318 entitled “System and Method to Improve Sequencing Accuracy of a Polymer” filed Feb. 28, 2008.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of Grant No. 1R43HG004466-01 awarded by the National Institutes of Health and under Grant No. FA9550-06-C-0006 awarded by the U.S. Air Force Office of Scientific Research.

### BACKGROUND OF THE INVENTION

The present invention pertains to the sequencing of individual monomers of a polymer and, more particularly, to increasing the sequencing accuracy of a nanopore-based system by controlling sequencing error rates and monomer identification error rates.

Extensive amounts of research and money are being invested to develop a method to sequence DNA, (Human Genome Project) by recording the signal of each base as the polymer is passed in a base-by-base manner through a recording system. Such a system could offer a rapid and low cost alternative to present methods based on chemical reactions with probing analytes and as a result might usher in a revolution in medicine.

Research in this area to date has focused on the question of developing a measurement system that can record a sufficient signal from each monomer in order to distinguish one monomer from another. In the case of DNA, the monomers are the well-known bases: adenine (A), cytosine (C), guanine (G), and thymine (T). It is necessary that the signals produced by each base be: a) different from that of the other bases, and b) be different by an amount that is substantially larger than the internal noise of the measurement device. For convenience, we will refer to this aspect of the sequencing as the Signal Amplitude Problem (SAP). The SAP is fundamentally limited by the specific property of the polymer being probed in order to differentiate the monomers and the signal to noise ratio (SNR) of the measurement device used to probe it.

A separate question, and one that has been overlooked to date, is the need to control, and thereby preserve, the order of the monomers while the measurement is made. We will refer to this as the Sequence Order Problem (SOP). For a polymer pulled through a measurement device it might seem that SOP is simply a question of providing a very well controlled pulling force. In a simple nanopore model, the polymer motion is one-dimensional, i.e. along the major axis of the polymer, and the total distance, s, the polymer has been displaced in time t is given by s=v_{DC}t, where v_{DC} is the average translocation velocity. However, such a model ignores the often critical effect of diffusion, which causes the polymer to move unpredictably. This phenomenon, also known as Brownian motion, results in a “random walk” such that the average net displacement in a given time t is proportional to (Dt)^{1/2} for an entity with diffusion rate D. This random motion is superimposed on the average translocation velocity resulting in an inherent uncertainty in the number of bases that have passed through the measurement device.

The diffusion rate D is given by D=D₀e^{-E/kT} in which D₀ is a constant, E is the activation energy, k is Boltzman's constant and T is temperature. The motion of a measured molecule is formally equivalent to that of a rigid particle moving between periodic potential energy wells separated by energy barriers of height E. For passage of DNA through a Is narrow pore, the motion can be approximated as one-dimensional, and can be represented by the one-dimensional potential shown in FIG. 1. For zero applied voltage across the pore, the potential wells all have the same energy. When a voltage is applied, the potential is tilted as shown in FIG. 1 resulting in an increased statistical probability that the point particle (i.e., the molecule) will move in the direction of decreasing energy.

The rate of motion of the molecule in a one-dimensional potential as shown in FIG. 1 can be calculated as a function of the activation energy using statistical methods know to those familiar in the art. For example, the rate κᵣ of jumping to the potential minima in the direction of decreasing potential is shown in Equation 1 below, in which V_{dc} is a bias voltage and n_{b}q is an effective electrical charge per DNA base.

$${κ}_{r} = \frac{1}{{τ}_{0}} \sqrt{1 + {( \frac{{n}_{b} {qV}_{dc}}{π E} )}^{2}} {e}^{- \frac{E}{kT} ( \sqrt{1 + {( \frac{{n}_{b} {qV}_{dc}}{π E} )}^{2}} + \frac{{n}_{b} {qV}_{dc}}{π E} {sin}^{- 1} \frac{{n}_{b} {qV}_{dc}}{π E} - \frac{{n}_{b} {qV}_{dc}}{2 E} )} \qquad [ 1 ]$$

The energy barrier shown in FIG. 1 is large compared to the tilt. In the case where the barrier is small and the amount of tilt produced by the applied voltage is large, then in the limiting case the barrier essentially disappears and the particle moves freely in the potential. In their seminal analysis of the diffusion of DNA in the protein pore alpha-hemolysin (αHL), Lubensky and Nelson estimated E to be several kT.

The diffusion constant of single stranded DNA in αHL under conditions of zero applied voltage was first measured by Mathe in 2003. The Mathe experiment only gave a value of D at 15° C. and was not sufficient to enable determination of the activation energy for diffusional processes in this system. Without knowing E, it is impossible to determine the extent to which diffusion affects, and within the limit dominates, the molecular motion under practical conditions. To the best of our knowledge, there have been no prior experiments to determine E for any kind of nanopore.

An idea of the effect of diffusion can be obtained by using the Mathe value of D for the case of zero voltage bias. For DNA threading αHL at 15° C. (the Mathe case) the net one-dimensional motion due to diffusion alone in 100 microseconds (μs) is calculated to be approximately 5 bases. Thus, in a notional example in which a given base is measured for 100 μs, the DNA would on average have moved a linear distance away from its desired position a total of 5 bases due to diffusion, resulting in an unacceptable SOP. In a second notional case in which a given base is measured for 20 μs and a total of five bases are measured, by the time the fifth base is measured the average error in the DNA position would again be 5 bases. This simple example shows that, if not taken into account, the diffusive motion of the polymer could quickly overwhelm any attempt to sequence it. Further, the positional errors occur no matter how sensitive the measurement device is that identifies each base.

One way to tackle the SOP is to reduce the time used to measure each base. In the simple example above, going to a measurement time per base of 1 μs would allow 5 bases to be measured in 5 μs, thereby reducing the mean random displacement due to diffusion to 0.5 bases. However, for any real recording system, reducing the measurement time tₘ significantly exacerbates the SAP. To date, no base-by-base serial method has been able to differentiate DNA bases in a single-base tₘ of order 10 μs because of inadequate measurement sensitivity. Reducing tₘ and, therefore, increasing the measurement bandwidth in inverse proportion, reduces the signal to noise ratio of the individual base measurement at least by an amount of order the square root of time reduction. Thus, for tₘ=1 μs the SNR relative to tₘ=100 μs is reduced by at least a factor of 10. Conversely, addressing the SOP directly by minimizing the effect of diffusion allows longer measurement times to be used, thereby alleviating the SAP.

To date, the impact of diffusion on systems that aim to sequence a polymer in a monomer-by-monomer or base-by-base serial manner has been overlooked. Owing to the very small distance between monomers, diffusion has the potential to greatly limit the ability of any measurement device to sequence a polymer above what might be required based on the need to record the signal from an individual monomer. What is needed in order to develop a practical polymer sequencing system is an approach that reduces the net uncertainty in position due to diffusion, and incorporates this improvement in the design of the measurement protocol in order to reduce the overall combined effect of the SAP and SOP.

### SUMMARY OF THE INVENTION

The system and method of the present invention utilizes a combination of measurement parameters to limit the sequencing error rate produced by diffusional motion of a polymer in solution in order to optimize the sequencing accuracy of the overall system and allow single-nucleotide level sequencing. The sequence error is the sum of the sequence order error rate (SOER) and the monomer identification error rate (MIER). More specifically, the SOER is the probability that a series of monomers or bases will be correctly identified but reported in the wrong sequence order. There are three types of sequence order error: 1) a base counting error in which the polymer does not move in the desired direction at the rate expected and the same base is inadvertently reported multiple times; 2) a base skipping error in which the polymer moves faster than expected and a base is not reported or the signals from one or more bases are correctly measured but inadvertently combined and reported as a single base; and 3) a base repeat error in which the polymer moves in the opposite of the desired direction and one or more bases are re-measured and inadvertently repeated in the reported sequence. The MIER is the probability that a base is measured erroneously and reported as a different base.

In accordance with the method of the present invention, a user selects a measurement device or system and one or more means for reducing the diffusional motion of a polymer within the system. In a preferred embodiment, the measuring system includes a first fluid chamber separated from a second fluid chamber by a barrier structure including a nanopore. The nanopore provides a fluid path connecting electrolytes in the first and second chambers. The system further includes electrodes extending into the first and second chambers, a power source, a controller and a temperature control stage for regulating the temperature of electrolytes in the first and second chambers. In use, electrical current signals sensed by the current sensor are processed in order to calculate the monomer sequence of a polymer driven through the nanopore.

Once a measurement device is selected, one or more means for reducing diffusional motion of a polymer to be sequenced are utilized, depending on the measurement device selected. Means for reducing the diffusional motion of a polymer include utilizing a modified nanopore adapted to increase the effective frictional force for polymer motion through the nanopore, cooling an electrolyte solution containing the polymer, utilizing an electrolyte solution adapted to reduce the diffusion constant of a polymer in the solution (such as an electrolyte having an increased salt concentration), or combinations thereof. Next, a major system parameter, such as average translocation velocity or measurement time, is selected based on the characteristics of the measurement device and an algorithm is utilized to jointly optimize the SOER and the MIER of the system. The algorithm is preferably performed on a computer system in communication with the controller of the measurement device. Although preferably utilized for single-nucleotide sequencing, the invention can be utilized in combination with any method that seeks to sequence a polymer, or indeed any method that measures a property of a polymer. However, when combined with new methods for improving pore current measurement sensitivity, the invention offers a means to enable sequencing of individual DNA molecules.

Additional objects, features and advantages of the present invention will become more readily apparent from the following detailed description of a preferred embodiment when taken in conjunction with the drawings wherein like reference numerals refer to corresponding parts in the several views.

### BRIEF DESCRIPTION OF THE DRAWINGS

FIG. 1 is a schematic representation of a point particle in a tilted one-dimensional potential;

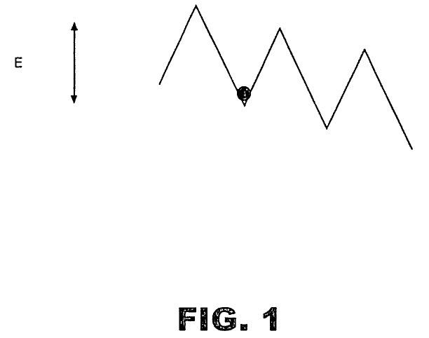

FIG. 2 is a cross-sectional view of an electrolytic sensing system compatible with the present invention;

FIG. 3 is a graph illustrating the effect of diffusion on sequencing error;

FIG. 4 is a graph presenting SNR vs. tₘ assuming both a measurement device with frequency independent noise, and a measurement device with noise increasing linearly with frequency;

FIG. 5 is a chair illustrating mean aggregate SNR vs. v_{DC} for fixed tₘ assuming frequency independent measurement system noise;

FIG. 6 illustrates a procedure to improve the combined sequencing order error rate due to sequence order error and monomer identification error in accordance with the invention;

FIG. 7 shows a first algorithm used to jointly optimize the error rate due to diffusion and to sensitivity in the measurement device in accordance with the invention; and

FIG. 8 shows a second algorithm used to jointly optimize the error rate due to diffusion and to sensitivity in the measurement device in accordance with the invention.

### DETAILED DESCRIPTION OF THE PREFERRED EMBODIMENT

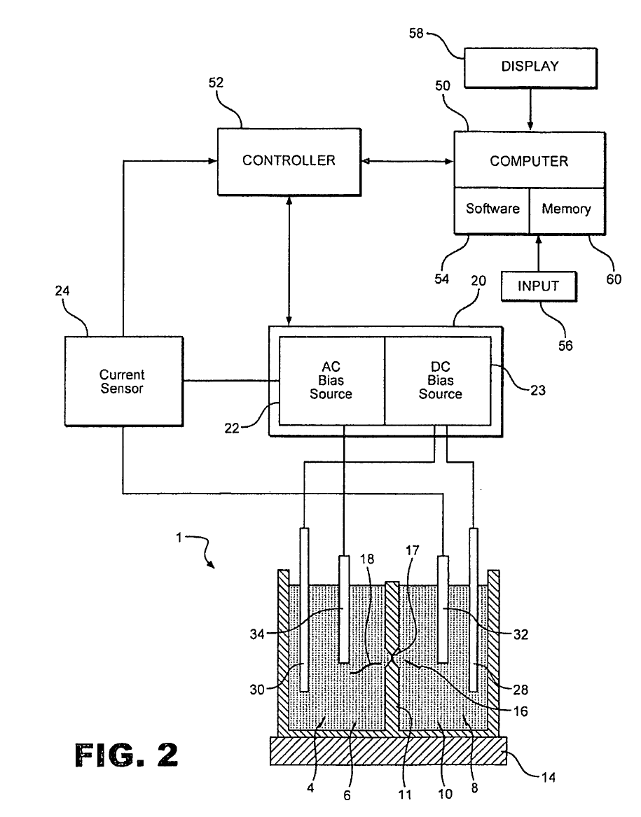

With initial reference to FIG. 2, a measurement device or sensing system 1 is utilized in accordance with the present invention in order to preserve the order in which monomeis are measured during sequencing. Sensing system 1 includes a first fluid chamber or electrolyte bath 4 within which is provided a first solution or electrolyte 6, and a second fluid chamber or sensing volume 8 provided with a second electrolyte 10. Sensing volume 8 is separated from electrolyte bath 4 by a barrier structure 11, which includes a thinned region 16 formed therein into which is incorporated a nanopore or nano-scale orifice 17 that provides a fluid path connecting first and second electrolytes 6 and 10. If region 16 is a solid material, orifice 17 can be formed by a variety of fabrication methods known to those skilled in the art. Alternatively, orifice 17 could be a biological entity, such as a protein pore or ion channel, and region 16 could be a biocompatible material chosen to incorporate such a pore or channel. Barrier structure 11 is joined to a substrate or stage 14. In a preferred embodiment of the present invention, stage 14 is a temperature control platform, although other temperature control means may be utilized to set the temperature of electrolyte 6 and 8 if desired. In general, measurement device 1 controls the translocation of a polymer 18 through orifice 17 utilizing a translocation means or means for controlling the velocity of a polymer through orifice 17 in the form of a power source 20. Electrolytes 6 and 10 are typically the same and biocompatible (e.g., 1 M KCl). In the embodiment shown, translocation power source 20 includes an AC bias source 22 and a DC bias source 23. In addition, a current sensor 24 is provided to measure the AC current through channel 16 produced by the AC bias source 22. More specifically, current sensor 24 is adapted to differentiate monomers of a polymer on the basis of changes in the electrical current that flows through orifice 17. In a manner known in the art, electrodes 28, 30, 32 and 34 are utilized in conjunction with current sensor 24 and power source 20. Current signals detected by current sensor 24 are processed in order to calculate the monomer sequence of polymer 18 as polymer 18 is driven through orifice 17. Alternatively, a DC current sensing system may be utilized to identify monomers within a polymer.

Orifice 17 must be small enough that polymer 18 produces a measurable blocking signal when located within the channel. In the case where polymer 18 is DNA, orifice 17 preferably has a diameter on the order of 2 nanometers (nm) at its narrowest point. In any case, at this point it should be realized that measurement device 1 is exemplary only, and the present invention can be employed with any type of system used in sequencing of individual monomers or a unique set of monomers of a polymer that is limited in its accuracy by the effect of diffusion. The term “nanopore” should be taken to include any structure that is used to guide a polymer so that its individual monomers or bases can be measured in a base-by-base manner. To this end, further details regarding some basic components of measurement device 1, as well as certain variants thereof, are set forth in pending U.S. Patent Application Publication No. 2008/0041733 entitled “Controlled Translation of a Polymer in an Electrolytic Sensing System” filed Aug. 16, 2007 which is incorporated herein by reference. Therefore, the above description is basically provided for the sake of completeness. The present invention is actually concerned with polymers in general and to any method that seeks to sequence a polymer. However, because of its technological significance and large body of existing experimental data, the specifics of the invention will be discussed further below in terms of sequencing DNA via a nano-scale pore. Although base-by-base sequencing is discussed, it should be understood that sequencing of unique monomer sets (such as a set of three adenine bases, for example), can also be improved utilizing the present method.

Experiments have shown that DNA passage through a nano-scale orifice of comparable diameter to the DNA is limited by an essentially frictional interaction, such that the average translocation velocity, v_{DC}, is proportional to the applied force. Because each base of DNA carries a net charge, a force to induce translocation through a pore can easily be applied by imposing an electric field across the pore. It is therefore s relatively straightforward to arrange for DNA to pass through a nanopore at any desired average velocity up to a limit that depends on the maximum allowable applied voltage, the effective friction of the pore, and the breaking force of the DNA. Similarly, the properties of various available approaches to measure the signal of an individual (or small number of) DNA bases are relatively well known and the duration of each individual measurement, tₘ, can be set over a range that is limited by the inherent signal to noise ratio (SNR) of the approach. In the work that has been done to date, v_{DC} and tₘ have been analyzed and preferred values postulated only in light of the signal amplitude problem (SAP) and large scale issues such as the overall total time required to sequence a human genome.

The present invention was premised on recognizing and establishing a path to reduce the diffusion driven motion of DNA in at least one system of significant technological relevance for sequencing. To this end, it has been determined that the rate of passage of DNA through an αHL protein pore can be reduced by orders of magnitude by methods that can be used singly, or in combination with each other. For example, mutating αHL or adding an internal adapter to reduce its internal dimensions will increase the energy barrier, E, resulting in a reduction in the diffusion rate, D. Similarly, there is an indication that increasing the electrolyte concentration and adding glycerol to a solution containing DNA can reduce the average translocation rate, v_{DC}, suggesting an increase in E and reduction in D. Finally, the inventors of the present invention have been able to explicitly show that the diffusion rate of DNA in αHL can be reduced by a factor of over 100 by cooling the electrolyte from 20° C. to −5° C. In one preferred embodiment of the present invention, an αHL-based measurement apparatus and protocol is provided to reduce diffusional motion of the target polymer 18. As will become more fully evident below, one or more of the above methods can be applied to other potential sequencing methods that share common features.

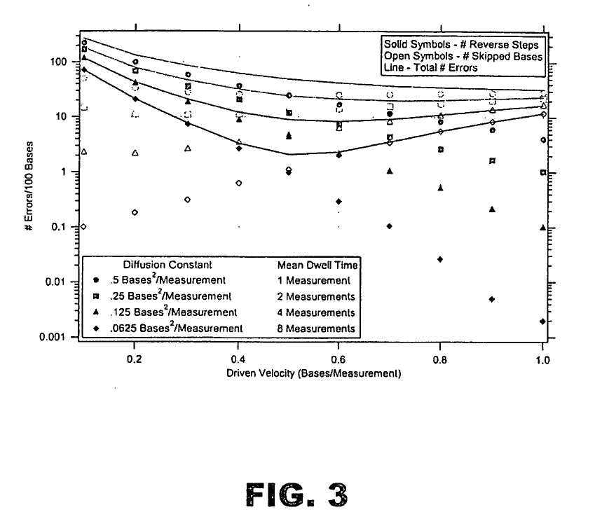

A detailed projection of the relationship between diffusion constant and two principal types of sequencing error is given in FIG. 3, in which each symbol is the result of approximately 10,000 numerical simulations of DNA passing through an αHL protein pore. The DNA is pulled through the measurement device at a constant velocity that is reported on the bottom axis in terms of the number of bases per measurement, ranging from 0.1 (i.e., 10 measurements per base) to 1. The vertical axis reports the number of errors per 100 bases of DNA passed through the system after beginning at a known position (i.e., zero initial position error). In the absence of considerations regarding diffusion, the time taken to make each individual measurement, tₘ, is set by the sensitivity of the measurement system. For reference, a present-day system that aims to differentiate DNA bases by their nanopore current blocking signal requires a tₘ of order 100 μs. In FIG. 3, results are plotted for four different values of DNA diffusion constant, each quantified in terms of the number of bases² per measurement made. Two first order components of sequence order error are plotted in FIG. 3. The solid symbols are errors caused by the DNA diffusing by one base in a direction opposite to that in which it is pulled through the device, resulting, for example, in the same base being measured twice. As shown, the faster the DNA is pulled the less likely it is that the DNA has time to diffuse back by an entire base in the opposite direction. The open symbols are errors due to the DNA diffusing forward by a base in the direction of travel. In this type of error, a base is skipped, and the number of errors increases with increasing velocity. In FIG. 3, the total error is the sum of the error due to diffusing back and forward. Because of the way these two types of sequence error vary with the driving velocity, there is, in this case, a shallow minimum at about 2 measurements per base.

It is important to note that the analysis summarized in FIG. 3 assumes that the SNR of the measurement device is sufficiently high that no errors are caused by misidentifying a base. In other words, FIG. 3 corresponds to the case in which the SAP is completely solved and so the monomer identification error rate (MIER)=0. However, we see that even in such an ideal scenario the effect of diffusion results in a significant sequence order problem (SOP). For the case discussed, above for DNA (at 15° C. confined in αHL), D is approximately 2×10⁻¹⁰ cm²/s or 1.25×10⁵ bases²/s. For a tₘ of order 100 μs, D=12.5 bases²/measurement. This value is higher than any of the curves plotted in FIG. 2 and would result in a diffusion driven error rate of >100 errors in 100 bases. Even if the accuracy of the measurement device was improved so that a tₘ of 10 μs was feasible, the resulting D=1.25 bases²/measurement is still higher than any case plotted in FIG. 3.

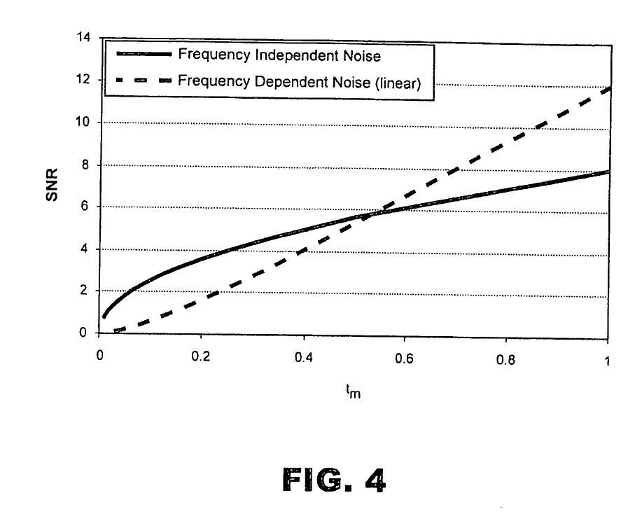

As indicated, the SOP can be reduced by reducing the time used to measure each base. A tₘ of 1 μs would produce a D value (at 15° C. in αHL) of 0.125 bases²/measurement, giving an error for the two components plotted in FIG. 2 of order 10%. However, in any measurement system, the SNR (and thus the MIER) of the measurement is also affected by tₘ. FIG. 4 shows the relationship between the SNR of a single measurement and tₘ for two example systems, one with frequency independent noise and one with noise that increases with frequency. For a measurement system that has frequency independent internal noise, at tₘ=1 μs the sensitivity relative to tₘ=100 μs is reduced by a factor of 10, owing to the proportional increase in measurement bandwidth. For means conventionally employed in measuring blocking current, the internal noise increases with frequency and the reduction in sensitivity is greater than 10 for a 100 times reduction in tₘ. Alternatively, if D could be reduced sufficiently, it might be possible to increase tₘ to order 1 ms, thereby providing an increase in sensitivity of order 3 or more, depending on the properties of the measurement device.

A preferable approach is to reduce diffusion to the greatest feasible extent and then to optimize the system based on its resulting properties. The example of FIG. 3 indicates that as the diffusion constant is reduced, the SOER can become a more sharply defined function of the average velocity of the polymer through the measurement device. For example, for D=0.0625 bases²/measurement, the sequencing order error rate at v_{DC}=0.5 is about 5 times less than for v_{DC}=1 and 30 times less than for v_{DC}=0.1.

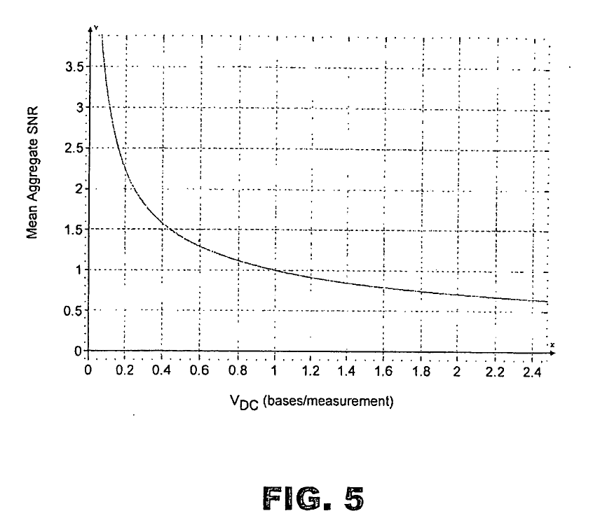

However, as v_{DC} is changed, the average number of measurements per base, N, changes. As N changes, the mean aggregate SNR of the measurement of an individual base, and so the MIER, will also change. FIG. 5 shows the variation in mean aggregate SNR with v_{DC} assuming a fixed tₘ and a measurement system with an internal noise spectrum that is white over the range of frequencies shown. The SNR varies as 1/v_{DC}^{0.5}, decreasing by a factor of 3.16 as v_{DC} increases from 0.1 to 1.

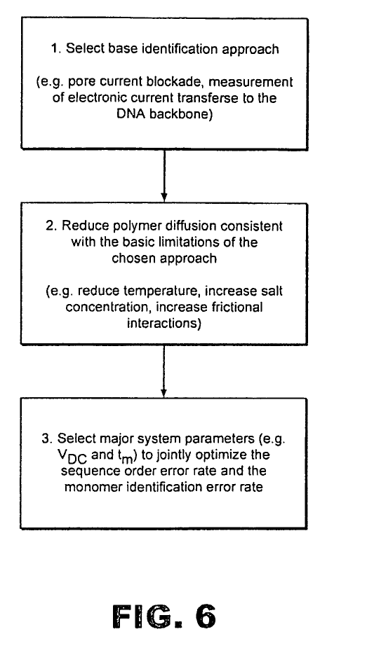

As discussed, the SNR of the measurement device determines the error rate in distinguishing one monomer from the others. This is the signal amplitude problem and the precise relationship between measurement device SNR and MIER depends on the specific technology used by the measurement device and the physical properties of the monomer that produce the measured signal. However, regardless of the exact functional relationship, it is clear from FIGS. 4 and 5 that varying the values of v_{DC} and tₘ to give a minimum SOER will also change the MIER. Accordingly, in a system built according to the invention, the internal measurement parameters are set according to the procedure described in FIG. 6.

With particular reference to FIG. 6, the first step in the method to improve sequencing accuracy of the present invention is to select a desired base identification measurement device. Step 1 is limited only in that the selected measurement device should in principal be able to produce a signal characteristic of each base of the polymer to be sequenced. Step 2 constitutes reducing polymer diffusion consistent with the basic limitations of the chosen device. The accuracy of a chosen device will be determined by the SNR of the basic technique and the values chosen for the core measurement parameters, for example, as shown in FIGS. 4 and 5. Given the present state of measurement technology, it is anticipated that the additions and modifications made in order to reduce diffusion (Step 2) will allow smaller v_{DC} and longer tₘ than are presently utilized, thereby improving the performance of currently available measurement devices.

Step 2 fundamentally addresses the SOP. Even if the SAP could be reduced to zero, or effectively zero in terms of the errors in distinguishing individual bases by appropriate design of the measurement device and appropriate setting of v_{DC} and tₘ, sequencing may be impossible due to randomization in the position of the bases due to diffusion. Thus, it is essential that the method and apparatus used to sequence the polymer be configured to take into account the contribution of polymer motion due to diffusion. A number of potential methods may be utilized to reduce the diffusion constant of a polymer in solution, including: reducing the temperature of the solution, adding an agent to increase viscosity such as glycerol, changing the ionic concentration of the electrolyte, and adding functional groups to the pore and/or adducts to the DNA that increase the effective friction through the pore. Additionally, secondary molecules can be utilized within the pore to reduce the diffusional motion of a polymer traveling through the pore. For example, with respect to measurement device 1, temperature stage 14 may be utilized to cool first and second electrolyte solutions 6 and 8, wherein electrolyte solutions 6 and 8 have an increased ionic concentration and a higher viscosity due to glycerol. Further, orifice 17 is preferably a protein pore mutated or chemically altered to increase the effective friction of polymer 18 through orifice 17 and may include a secondary or adaptor molecule (not shown) to decrease the internal diameter of orifice 17. The method or combination of methods that is used will depend on the type of measurement approach chosen in Step 1. Once the apparatus is constructed, the diffusion parameters can be quantified by methods known to those familiar with the art for the type and length of polymer to be sequenced.

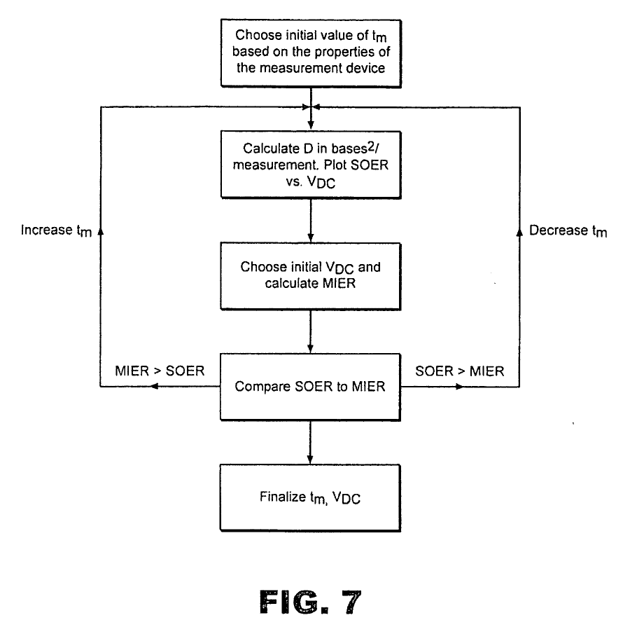

In Step 3, major system parameters, such as v_{DC} and tₘ, are selected to jointly optimize the SOER and the MIER. In accordance with the invention, the innovation of controlling polymer diffusion is combined with the inherent trade-offs in the performance of the base identification approach in an algorithm to minimize the combination of the SOER and the MIER. The basic structure of a preferred algorithm is summarized in FIG. 7. The first step in the algorithm is to pick an initial value for the time between measurement points tₘ. This time should be based on the SNR properties of the base identification approach. Next, the measured value of D is utilized to estimate a first value of v_{DC} to give an optimum, or approximately optimum value of SOER. One way to estimate a first value for v_{DC} is to calculate the number of bases² per measurement from the measured value of D. Calculating D in these units then allows a curve of SOER vs. v_{DC} to be plotted in the manner of FIG. 3, for example, in which curves for four values of D are shown. Inspection of the curve allows the initial value of v_{DC} to be chosen. The value of v_{DC} can then be transformed back into common physical units (e.g., μm/s) via the chosen value of tₘ.

In the analysis of the SOER summarized in FIG. 3, the initial value of v_{DC} generally corresponds to an average total number of measurements per base, N, of 2. We note that the mean measurement time per base t_{b}=N tₘ and N=2 allows for an mean aggregate SNR increase of 41% compared to a single measurement for a base identification method with frequency independent noise. In any case, based on the modified SNR, the MIER can be projected based on the properties of the measurement device. It should be noted that FIG. 3 relates D, v_{DC} and SOER through an analysis of only two components of the sequence error. In the preferred embodiment, this analysis would be extended to all reasonable types of sequencing error, or be based on empirical calibration.

Most likely, for the initial value of the average total number of data points per base, the SOER and MIER will not be identical, and one will dominate the other. In that case, a new value of tₘ is chosen and the process repeated as shown in FIG. 7. If the MIER is greater than the SOER then the MIER can be reduced by increasing tₘ. Increasing tₘ increases D (as measured in units of bases²/measurement) and thereby increases the SOER. If the MIER is smaller than the SOER, then the MIER can be increased by reducing tₘ. Reducing tₘ reduces D thereby reducing the SOER. The sum of MIER and SOER gives the total sequencing error rate. Once the combination of the SOER and MIER has been balanced to reach an acceptable value, the value of v_{DC} should be set as high as possible in order to maximize the number of bases sequenced per unit time.

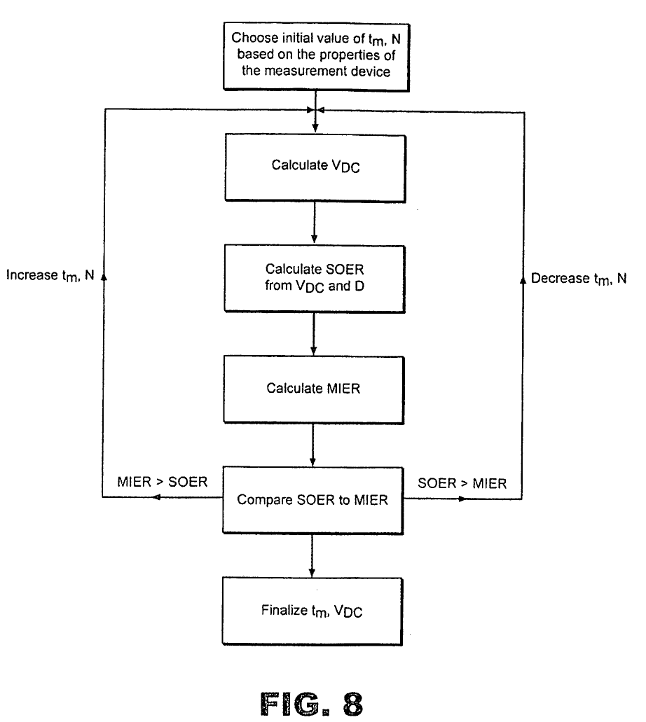

Alternatively, as depicted in FIG. 8, a first value of tₘ and N is estimated using the measured value of D to give an adequate average total measurement time, t_{b}, per base in order to give an acceptable initial value for MIER. Dividing the known physical spacing between the polymer bases by the chosen value of tₘ gives the value of v_{DC}. From the known statistics of thermally activated hopping for the measured D and calculated v_{DC} the probabilities of jumping back (repeating bases), jumping forward too fast (skipping bases) and not jumping in the measurement time (overcounting bases) can be calculated. The total of these three probabilities gives the SOER.

As before, the MIER and resulting SOER are then compared and in this latter case, if MIER>SOER the product of tₘ and N is increased and the algorithm repeated. If MIER<SOER then the product of tₘ and N is reduced and the algorithm is repeated. Once the product of tₘ and N has been set so that the combination of the SOER and MIER has been balanced to reach an acceptable value, the value of tₘ should be made as small as possible consistent with the engineering and cost limitations of acquiring the data very quickly. The smaller tₘ, the higher the time resolution will be to capture signals from bases that do not remain in the pore long due to random diffusion driven motion.

As can be seen by comparing the first algorithm depicted in FIG. 7 with the second algorithm depicted in FIG. 8, the algorithms are fundamentally similar and only differ in the selection of which variables are given initial values and then iterated over to reduce the sum of MIER and SOER. In a third similar algorithm, v_{DC} is chosen as the initial variable and SOER determined from a plot such as FIG. 3, or by calculation from the statistics of thermal diffusion as described above for the second algorithm. For this third algorithm, if MIER>SOER, v_{DC} is reduced and the process repeated, and conversely, if MIER<SOER then v_{DC} is increased.

These three algorithms are given as examples of the overall process of varying the system parameters of tₘ, N and v_{DC} in order to reduce the total sequence error rate, and are not meant to be limiting in their specific embodiments. In all cases the average time the system is expected to remain recording one specific base is used in combination with the statistics of diffusion to calculate the SOER.

Generally, the goal is to reduce diffusion as much as practically possible. However, depending on the physical properties of the measurement device, the modifications made to reduce diffusion (e.g., cooling the electrolyte) may directly alter the SNR measured for each base. In this case, the balance between SOER and MIER will involve multiple adjustable parameters. The final system setting will be a synergistic combination of these two or more parameters and a clear optimum setting may not exist, but rather a broad range of possible operating conditions will be applicable. Nevertheless, regardless of the complexity of the balancing condition, a trade-off between the SOER and the MIER is required for a practical sequencing system.

The means for calculating measurement device parameters to jointly balance SOER and MIER may be in the form of a computer 50, or may be standard iterative human calculation methods. For example, as depicted in FIG. 2, a computer 50 is in communication with both measurement device 1 and a controller 52 connected to power source 20 of measurement device 1. Computer 50 includes software 54 configured to perform one of the above-discussed algorithms, or an equivalent algorithm, in accordance with the method of the present invention. Computer 50 additionally includes an input device indicated at 56 for entering information pertaining to measurement device 1, a display 58 for viewing information, and a memory 60 for storing information. The algorithm can be calculated in advance based on laboratory measurements or calibration of a first system, and the balance thereby derived applied in the system settings of future sequencing systems. Alternatively, the algorithm is recalculated as part of the system operation each time any of the basic system internal properties are changed, for example, when the concentration of the electrolyte is changed. Once an acceptable set of internal parameters is found, the system can be further optimized by making small variations in each parameter and recording the resulting dependence on the combined SOER+MIER. Once a system is fully characterized, the dependency on each system parameter is fit to a mathematical function and solved for the optimum system operating point via standard numerical minimization methods. Polymers may then be sequenced utilizing the optimized detecting system, wherein individual monomers of the polymer are identified sequentially.

Advantageously, the present invention addresses not only the SOP of a system, but the SAP as well, and provides a system and method for balancing a measurement device in such a way that synergistic results are obtained, allowing unprecedented sensitivity and single-nucleotide sequencing. Although described with reference to a preferred embodiment of the invention, it should be readily understood that various changes and/or modifications can be made to the invention without departing from the spirit thereof. In general, the invention is only intended to be limited by the scope of the following claims.

I/We claim:

1. A system for improving the accuracy in sequencing a polymer comprising:
a measurement device adapted to produce a signal indicative of each monomer or unique set of monomers of the polymer;
a diffusional motion reducer for reducing diffusional motion of the polymer being sequenced; and
a calculating device for calculating measurement device parameters to jointly balance a sequencing order error rate and a monomer identification error rate of the measurement device.

2. The system of claim 1, further comprising a controller for controlling an average velocity of a polymer being sequenced.

3. The system of claim 1, wherein the measurement device is adapted to measure a signal indicative of each monomer or unique set of monomers of the polymer by interrogating the polymer in a serial manner.

4. The system of claim 1, wherein the measurement device is adapted to differentiate monomers or unique sets of monomers of the polymer on the basis of pore blocking current.

5. The system of claim 3, further comprising: a nanopore through which the polymer is directed.

6. The system of claim 5, wherein the nanopore is a modified nanopore adapted to increase the effective frictional force for polymer motion through the nanopore, with the modified nanopore constituting the diffusional motion reducer.

7. The system of claim 5, wherein the nanopore comprises a biological entity.

8. The system of claim 7, wherein the nanopore is a mutated biological protein pore, and the mutated biological protein pore constitutes the diffusional motion reducer.

9. The system of claim 7, wherein the nanopore is a biological protein pore and the diffusional motion reducer comprises an adapter molecule adapted for insertion in the biological protein pore.

10. The system of claim 1, wherein the diffusional motion reducer comprises a cooling stage adapted to cool a solution containing the polymer.

11. The system of claim 1, wherein the diffusional motion reducer comprises a solution adapted to reduce the diffusion constant of a polymer in the solution.

12. The system of claim 11, wherein the solution includes glycerol.

13. The system of claim 1, wherein the diffusional motion reducer is selected from the group consisting of a modified nanopore adapted to increase the effective frictional force for polymer motion through the nanopore, a cooling stage adapted to cool a solution containing the polymer, a solution adapted to reduce the diffusion constant of a polymer in the solution, an adapter molecule adapted for insertion in the biological protein pore, a modification to the polymer, and a combination thereof.

14. The system of claim 1, wherein the calculating device includes computer software that runs an algorithm.

15. The system of claim 14, wherein the algorithm principally functions by varying the measurement time per data point.

16. The system of claim 15, wherein the algorithm functions by first setting a value of the average measurement time per monomer or unique set of monomers.

17. The system of claim 14, wherein the algorithm principally functions by varying a total average measurement time per monomer or unique set of monomers.

18. A system for improving the accuracy in sequencing a polymer comprising:
a measurement device adapted to produce a signal indicative of each monomer or unique set of monomers of the polymer;
means for reducing diffusional motion of the polymer being sequenced; and
means for calculating measurement device parameters to jointly balance a sequencing order error rate and a monomer identification error rate of the measurement device.

19. A method for improving the accuracy in sequencing a polymer in solution utilizing a measurement device comprising:
relating a first system parameter to a monomer identification error rate for the polymer;
reducing diffusional motion of the polymer in solution;
relating a second system parameter to a sequencing order error rate for the polymer;
determining a total average measurement time per monomer or unique set of monomers and an average polymer translocation velocity using the first system parameter and the second system parameter; and
adjusting the first and second system parameters to jointly balance the sequencing order error rate and the monomer identification error rate.

20. The method of claim 19, wherein at least one of the first and second system parameters has units of time.

21. The method of claim 19, wherein at least one of the first and second system parameter has units of velocity.

22. The method of claim 19, further comprising: iteratively adjusting the first system parameter so as to reduce the overall sequence error rate.

23. The method of claim 19, further comprising:
adjusting the first system parameter incrementally;
recording a dependency of the sequencing order error rate and the monomer identification error rate on the first system parameter;
fitting the recorded dependency to a mathematical function; and
solving for an improved system operating point for the first system parameter.

24. The method of claim 19, further comprising:
adjusting the second system parameter incrementally;
recording a dependency of the sequencing order error rate and the monomer identification error rate on the second system parameter;
fitting the recorded dependency to a mathematical function; and
solving for an improved system operating point for the second system parameter.

25. The method of claim 19, wherein the accuracy in sequencing of the polymer is performed with a nanopore sensing system and reducing the diffusional motion of the polymer includes reducing diffusion associated with the nanopore sensing system consistent with basic limitations of the nanopore sensing system.

26. The method of claim 25, further comprising:
establishing an initial measurement time based on properties of the nanopore sensing system;
calculating an initial translocation velocity of the polymer in the nanopore sensing system based on the initial measurement time;
deriving a relationship between the sequencing order error rate and the monomer identification error rate; and
selecting a final measurement time and a final translocation velocity.

27. A method of claim 25, wherein reducing polymer diffusion constitutes at least one of reducing a temperature of an electrolyte of the nanopore sensing system, increasing a salt concentration of the electrolyte, increasing a viscosity of the solution containing the polymer, and increasing frictional interactions of the polymer with an ion-channel in the nanopore sensing system.
